(19) United States
(12) Patent Application Publication
(10) Pub. No.: US 2026/0229839 A1
(43) Pub. Date: Aug. 6, 2026

(54) SURFACE-EMITTING LASER ELEMENT

(71) Applicants: KYOTO UNIVERSITY, Kyoto-shi, Kyoto (JP); STANLEY ELECTRIC CO., LTD., Meguro-ku, Tokyo (JP)

(72) Inventors: Susumu NODA, Kyoto (JP); Kei EMOTO, Tokyo (JP); Tomoaki KOIZUMI, Tokyo (JP); Takako FUJIWARA, Tokyo (JP)

(73) Assignees: KYOTO UNIVERSITY, Kyoto-shi, Kyoto (JP); STANLEY ELECTRIC CO., LTD., Meguro-ku, Tokyo (JP)

(21) Appl. No.: 19/152,732

(22) PCT Filed: Jan. 29, 2024
(86) PCT No.: PCT/JP2024/002703

§ 371 Date: Jul. 31, 2025

(30) Foreign Application Priority Data
Feb. 1, 2023 (JP) 2023-013724

(51) Int. Cl. H01S 5/024; H01S 5/0234; H01S 5/042; H01S 5/187; H01S 5/20

(52) U.S. Cl. CPC H01S 5/02461; H01S 5/0234; H01S 5/02476; H01S 5/04253; H01S 5/04254; H01S 5/187; H01S 5/2027; H01S 5/2045

(57) ABSTRACT

A surface-emitting laser element includes a light-transmissive substrate, a first semiconductor layer in which an air-hole layer that serves as a photonic crystal layer is formed, an active layer on the first semiconductor layer, a second semiconductor layer on the active layer, a current confinement layer on the second semiconductor layer having a contact opening in a circular or rotationally symmetric shape, a contact electrode formed by filling the contact opening, and a pad electrode on the contact electrode and inside which a thermal conductivity adjustment layer having a thermal conductivity lower than an effective thermal conductivity of the second semiconductor layer is buried. The thermal conductivity adjustment layer has a thermal conductivity adjustment opening having a central axis that is coaxial with the contact opening, and the thermal conductivity adjustment opening has an opening diameter (W2) smaller than an opening diameter (W1) of the contact opening.

### TECHNICAL FIELD

The present invention relates to a surface-emitting laser element, and particularly relates to a surface-emitting laser element including a photonic crystal.

### BACKGROUND ART

Recently, development has progressed on a photonic-crystal surface-emitting laser (PCSEL) that utilizes a photonic crystal (PC).

In a photonic crystal laser, the resonance wavelength is determined by the lattice constant of the photonic crystal and the effective refractive index of the guided mode. In continuous-wave (CW) oscillation of a photonic crystal laser, it is known that temperature distribution due to heat generation occurs in a current injection region, and this temperature distribution causes in-plane distribution of the resonance wavelength, which adversely affects laser characteristics.

In particular, the influence of such heat generation is significant in a nitride (GaN)-based semiconductor photonic crystal laser due to high drive voltage and high electric resistance of the semiconductor material.

For example, Patent Literature 1 discloses an invention in which the sizes of air holes of a photonic crystal are adjusted in accordance with temperature distribution.

Patent Literature 1 also describes that the sizes of air holes or the lattice constant of the photonic crystal are adjusted in accordance with temperature distribution.

### CITATION LIST

### Patent Literature

[Patent Literature 1] Japanese Patent Application Publication (Republication) No. 2017-038595

### Non Patent Literature

[Non Patent Literature 1] S. Katsuno, T. Inoue, M. Yoshida, M. D. Zoysa, K. Ishizaki, and S. Noda, “Self-consistent analysis of photonic-crystal surface-emitting lasers under continuous-wave operation,” Opt. Express Vol. 29, No. 16, 25118-25132 (2021).

[Non Patent Literature 2] Koizumi et al., “Continuous-wave operation of a blue photonic crystal laser”, The 69th Spring Meeting of the Japan Society of Applied Physics, [25p-E303-13].

### SUMMARY OF INVENTION

### Technical Problem

However, in order to adjust the sizes and the lattice constant of a photonic crystal in accordance with temperature distribution, extremely high precision control on the order of nanometers or less is required. Such extremely high precision adjustment is very difficult and also difficult to verify during manufacturing. Furthermore, there have been problems in that the manufacturing reproducibility is poor and the production yield is low.

The present invention has been made in view of the above and is intended to provide a photonic-crystal surface-emitting laser in which temperature distribution in a photonic crystal can be easily flattened during continuous-wave (CW) drive, thereby improving light emission efficiency and achieving excellent oscillation stability.

### Solution to Problem

A surface-emitting laser element according to one aspect of the present invention includes:
a substrate that is light-transmissive;
a first semiconductor layer which is formed on the substrate and in which an air-hole layer that serves as a photonic crystal layer is formed;
an active layer formed on the first semiconductor layer;
a second semiconductor layer formed on the active layer;
a current confinement layer formed on the second semiconductor layer and having a contact opening in a circular shape or a rotationally symmetric shape;
a contact electrode formed by filling the contact opening of the current confinement layer; and
a pad electrode which is formed on the contact electrode and inside which a thermal conductivity adjustment layer having a thermal conductivity lower than an effective thermal conductivity of the second semiconductor layer is buried, wherein
the thermal conductivity adjustment layer has a thermal conductivity adjustment opening having a central axis that is coaxial with the contact opening, and the thermal conductivity adjustment opening has an opening diameter (W2) smaller than an opening diameter (W1) of the contact opening.

A surface-emitting laser element according to another aspect of the present invention is a surface-emitting laser element including a photonic crystal, and includes:
a substrate that is light-transmissive;
a first semiconductor layer which is formed on the substrate and in which an air-hole layer that serves as a photonic crystal layer is formed;
an active layer formed on the first semiconductor layer;
a second semiconductor layer formed on the active layer;
a contact electrode that is partially formed on the second semiconductor layer and is in ohmic contact with the second semiconductor layer;
a thermal conductivity adjustment layer that is formed on the second semiconductor layer, overlaps an outer peripheral portion of the contact electrode, has a thermal conductivity adjustment opening formed so as to partially cover an upper surface of the outer peripheral portion and expose the second semiconductor layer, and is constituted by a layer including at least one material selected from insulators and semiconductors having a thermal conductivity lower than an effective thermal conductivity of the second semiconductor layer; and
a metal electrode formed so as to fill the thermal conductivity adjustment opening of the thermal conductivity adjustment layer and cover at least an entirety of the contact electrode in a top view.

A surface-emitting laser element according to a further aspect of the present invention is a surface-emitting laser element including a photonic crystal, and includes:
a substrate that is light-transmissive;
a first semiconductor layer which is formed on the substrate and in which an air-hole layer that serves as a photonic crystal layer is formed;
an active layer formed on the first semiconductor layer;
a second semiconductor layer formed on the active layer;
a current confinement layer formed on the second semiconductor layer and having a contact opening;
a contact electrode formed by filling the contact opening of the current confinement layer;
a metal electrode formed on the contact electrode;
a bonding metal formed on the metal electrode;
a heat-dissipating substrate bonded to the bonding metal by the bonding metal; and
a thermal conductivity adjustment layer provided inside one of the metal electrode, the bonding metal, and the heat-dissipating substrate, wherein
the thermal conductivity adjustment layer includes at least one material selected from insulators and semiconductors having a thermal conductivity lower than at least one of the bonding metal and the heat-dissipating substrate, and
the thermal conductivity adjustment layer has a thermal conductivity adjustment opening, and the thermal conductivity adjustment opening has a size and disposition such that the thermal conductivity adjustment opening is contained within the contact opening in a top view.

### BRIEF DESCRIPTION OF DRAWINGS

FIG. 1A is a cross-sectional view schematically illustrating an example of the structure of a PCSEL element according to a first embodiment of the present invention.

FIG. 1B is a partially enlarged cross-sectional view of FIG. 1A, schematically illustrating an air-hole layer and air holes arrayed in the air-hole layer.

FIG. 2A is a plan view schematically illustrating the upper surface (from which a pad electrode is removed) of the PCSEL element.

FIG. 2B is a cross-sectional view schematically illustrating a section of the air-hole layer along a plane parallel to an n-side guide layer.

FIG. 2C is a plan view schematically illustrating the lower surface of the PCSEL element.

FIG. 3 is a diagram schematically illustrating an example of an air-hole array in a plane parallel to the air-hole layer.

FIG. 4 is a cross-sectional view illustrating a surface-emitting laser device constituted by a PCSEL element mounted on a submount.

FIG. 5 is a diagram illustrating a calculation result of finite element analysis of temperature distribution in the air-hole layer of a PCSEL element provided with no temperature adjustment layer.

FIG. 6 is a diagram illustrating a calculation result of temperature distribution in the air-hole layer for the PCSEL element (EMB1) according to the first embodiment.

FIG. 7A is a cross-sectional view schematically illustrating an example of the structure of a PCSEL element (EMB2) according to a second embodiment.

FIG. 7B is a plan view schematically illustrating the upper surface of a thermal conductivity adjustment layer of the PCSEL element illustrated in FIG. 7A.

FIG. 8 is a diagram illustrating a calculation result of temperature distribution in the air-hole layer for the PCSEL element (EMB2).

FIG. 9A is a cross-sectional view schematically illustrating an example of the structure of a PCSEL element (EMB3) according to a third embodiment.

FIG. 9B is a plan view schematically illustrating the upper surface of the thermal conductivity adjustment layer of the PCSEL element illustrated in FIG. 9A.

FIG. 10 is a cross-sectional view schematically illustrating an example of the structure of a PCSEL element (EMB4) according to a fourth embodiment.

FIG. 11A is a cross-sectional view schematically illustrating an example of the structure of a PCSEL element (EMB5) according to a fifth embodiment

FIG. 11B is a cross-sectional view schematically illustrating an example of the structure of a PCSEL element as a modification of the fifth embodiment.

FIG. 12 is a cross-sectional view schematically illustrating an example of the structure of a PCSEL element (EMB6) according to a sixth embodiment.

FIG. 13A is a top view schematically illustrating Modification 1 of the thermal conductivity adjustment layer.

FIG. 13B is a top view schematically illustrating Modification 2 of the thermal conductivity adjustment layer.

FIG. 13C is a top view schematically illustrating Modification 3 of the thermal conductivity adjustment layer.

FIG. 13D is a top view schematically illustrating Modification 4 of the thermal conductivity adjustment layer.

FIG. 14A is a cross-sectional view schematically illustrating the structure of a PCSEL element according to a seventh embodiment.

FIG. 14B is a plan view schematically illustrating the upper surface of the PCSEL element.

FIG. 15A is a graph illustrating a calculation result of temperature distribution in the air-hole layer for the PCSEL element according to the seventh embodiment.

FIG. 15B is a graph illustrating a calculation result of temperature distribution in the air-hole layer for a comparative-example PCSEL element provided with no thermal conductivity adjustment layer.

FIG. 16A is a cross-sectional view schematically illustrating the structure of a PCSEL element according to an eighth embodiment.

FIG. 16B is a plan view schematically illustrating the upper surface of the PCSEL element.

FIG. 17 is a graph illustrating calculation results of temperature distribution in the air-hole layer for the PCSEL elements according to the eighth embodiment and the comparative example in comparison.

FIG. 18 is a cross-sectional view schematically illustrating the structure of a PCSEL element according to Modification 1 of the eighth embodiment.

FIG. 19 is a cross-sectional view schematically illustrating the structure of a PCSEL element according to Modification 2.

FIG. 20 is a cross-sectional view schematically illustrating the structure of a PCSEL element according to Modification 3.

FIG. 21 is a cross-sectional view schematically illustrating the structure of a PCSEL element according to Modification 4.

FIG. 22 is a cross-sectional view schematically illustrating the structure of a PCSEL element according to a ninth embodiment.

FIG. 23A is a graph illustrating calculation results of temperature distribution in the air-hole layer for the PCSEL elements according to the ninth embodiment and the comparative example in comparison.

FIG. 23B is a graph illustrating calculation results of the resonance center wavelength for the PCSEL elements according to the ninth embodiment and the comparative example in comparison.

FIG. 24 is a cross-sectional view illustrating another example of the PCSEL element according to the ninth embodiment.

### DESCRIPTION OF EMBODIMENTS

Preferable embodiments of the present invention, which will be described below, may be modified and combined as appropriate. In the following description and accompanying drawings, parts that are identical or equivalent in effect are denoted by the same reference sign.

### First Embodiment

### 1. Structure of Photonic-Crystal Surface-Emitting Laser

### (a) Element Structure

A photonic-crystal surface-emitting laser (hereinafter also referred to as PCSEL) is an element that includes a resonator layer parallel to a semiconductor light-emitting structure layer (n-side guide layer, light-emitting layer, and p-side guide layer) constituting a light-emitting element and emits coherent light in a direction orthogonal to the resonator layer.

Specifically, in a photonic-crystal surface-emitting laser (PCSEL), light waves propagating in a plane parallel to a photonic crystal layer (air-hole layer) are diffracted by the photonic crystal's diffraction effect, thereby forming a two-dimensional resonance mode, and are also diffracted in a direction orthogonal to the parallel plane. In other words, in a photonic-crystal surface-emitting laser, the light extraction direction is orthogonal to a resonance direction (in a plane parallel to the air-hole layer).

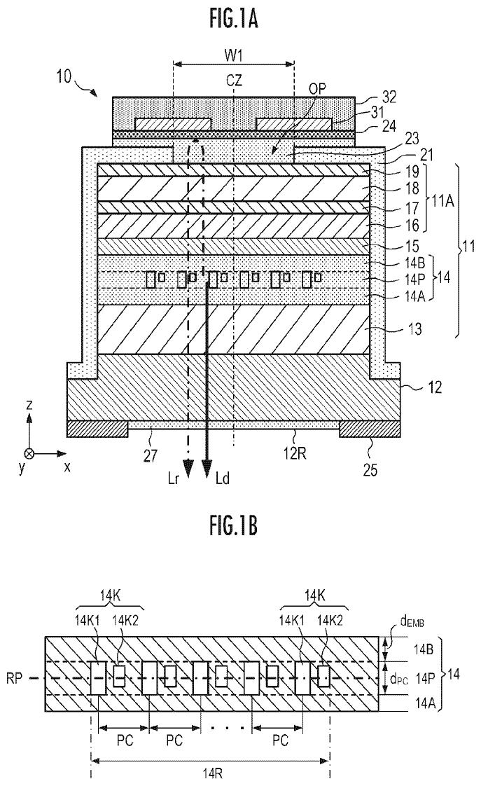

FIG. 1A is a cross-sectional view schematically illustrating an example of the structure of a photonic-crystal surface-emitting laser element (hereinafter referred to as PCSEL element) 10 according to a first embodiment of the present invention. FIG. 1B is an enlarged cross-sectional view of FIG. 1A, schematically illustrating an air-hole layer 14P and pairs of air holes 14K arrayed in the air-hole layer 14P.

As illustrated in FIG. 1A, a semiconductor structure layer 11 is formed on a substrate 12 that is light-transmissive. The semiconductor structure layer 11 is made of a hexagonal nitride semiconductor. In the present embodiment, the semiconductor structure layer 11 is made of, for example, a gallium nitride (GaN)-based semiconductor.

More specifically, the semiconductor structure layer 11 constituted by a plurality of semiconductor layers, namely, an n-clad layer (first clad layer of a first conductivity type) 13, an n-side guide layer (first guide layer) 14 that is a guide layer provided on an n side, an active layer (ACT) 15, a p-side guide layer (second guide layer) 16 that is a guide layer provided on a p side, an electron blocking layer (EBL) 17, a p-clad layer (second clad layer of a second conductivity type) 18, and a p-contact layer 19 are formed in the stated order on the substrate 12.

Hereinafter, the entirety of semiconductor layers provided on the active layer 15, namely, the p-side guide layer 16, the electron blocking layer 17, the p-clad layer 18, the p-contact layer 19 in the case of the present embodiment is collectively referred to as a second semiconductor layer (p semiconductor layer) 11A.

Note that description will be made of a case where the first conductivity type is n-type and the second conductivity type, which is opposite to the first conductivity type, is p-type, but the first and second conductivity types may be p-type and n-type, respectively.

The substrate 12 is a hexagonal GaN single crystal and has high transmittance to light emitted from the active layer 15. More specifically, the substrate 12 is a hexagonal GaN single crystal substrate the principal surface (crystal growth surface) of which is a +c-plane face in which Ga atoms are arrayed on the outermost surface.

The back surface (light emission surface including a light emission region 20L) opposite to the principal surface is a −c-plane (000-1) face in which N atoms are arrayed on the outermost surface. The −c-plane is resistant to oxidation and the like and thus suitable as a light emission surface.

The substrate 12 is not limited thereto but is preferably what is called a just-cut substrate or, for example, a substrate the principal surface of which is offset by up to approximately 1° in the m-axis direction or the a-axis direction. For example, a substrate that is offset by up to approximately 1° in the m-axis direction can achieve mirror-surface growth under a wide range of growth conditions.

The compositions, layer thicknesses, and other structures of respective semiconductor layers will be described below, but they are merely exemplary and may be modified and applied as appropriate.

The n-clad layer 13 is, for example, an n-Al_{0.04}Ga_{0.96}N layer having an Al composition of 4%, and has a layer thickness of 2 μm. The aluminum (Al) composition ratio is set such that the refractive index is lower than that of an adjacent layer (in other words, the n-side guide layer 14) on the active layer 15 side.

The n-side guide layer 14 is constituted by a lower guide layer 14A, an air-hole layer 14P that serves as a photonic crystal layer, and an embedding layer 14B. As illustrated in FIG. 1B, the air-hole layer 14P has a layer thickness (depth) dec, and the embedding layer 14B has a layer thickness dEMB.

The lower guide layer 14A is, for example, an n-GaN having a layer thickness of 300 nm. The air-hole layer 14P is an n-GaN having a layer thickness (or depth of the air holes 14K) of, for example, 90 nm.

The embedding layer 14B is made of n-GaN, n-InGaN, undoped GaN, or undoped InGaN. Alternatively, the embedding layer 14B may be a layer in which these semiconductor layers are stacked. The embedding layer 14B has a layer thickness of, for example, 120 nm.

The active layer 15 as a light-emitting layer is, for example, a multiple quantum well (MQW) layer including two quantum well layers. The barrier layers and quantum well layers of the MQW are GaN (with a layer thickness of 3.0 nm) and InGaN (with a layer thickness of 3.0 nm), respectively. The oscillation wavelength of the active layer 15 is, for example, 432 nm.

Note that the active layer 15 is preferably disposed within 180 nm from the air-hole layer 14P. In this case, a high resonance effect is obtained due to the air-hole layer 14P.

The p-side guide layer 16 is made of, for example, undoped GaN or undoped InGaN and has a layer thickness of 250 nm. Note that the p-side guide layer 16 is an undoped layer in consideration of light absorption due to dopants, but may be doped with magnesium (Mg) or the like to achieve favorable electrical conductivity.

The electron blocking layer (EBL) 17 is a p-type Al_{0.2}Ga_{0.8}N layer doped with magnesium (Mg) and has a layer thickness of, for example, 15 nm.

The p-clad layer 18 is a Mg-doped p-Al_{0.06}Ga_{0.94}N layer and has a layer thickness of, for example, 300 nm. The Al composition of the p-clad layer 18 is preferably selected such that its refractive index is lower than that of the p-side guide layer 16.

The p-contact layer 19 is a Mg-doped p-GaN layer and has a layer thickness of, for example, 25 nm. The carrier concentration of the p-contact layer 19 is set to a concentration that allows ohmic contact with a p electrode 23 provided on its surface. P-type InGaN may be used in place of p-type GaN. Alternatively, a layer in which a GaN layer and an InGaN layer are stacked may be used.

Note that, in the present specification, “n side” and “p side” do not necessarily mean that the corresponding components have n-type or p-type conductivity. For example, an n-side guide layer means a guide layer provided on the n side of the active layer and may be an undoped layer (or i-layer).

The n-clad layer 13 may be constituted by a plurality of layers instead of a single layer, and in this case, not all layers need to be n-layers (n-doped layer), but undoped layers (i-layers) may be included. This applies to the guide layer 16 and the p-clad layer 18 as well.

Not all semiconductor layers described above need to be provided, but the configuration only needs to include a first semiconductor layer of the first conductivity type, which includes an air-hole layer, a second semiconductor layer of the second conductivity type, and an active layer (light-emitting layer) sandwiched between these layers.

The side surface and upper surface of the semiconductor structure layer 11 are covered with an insulating film 21 such as SiO₂. The insulating film 21 is provided with an opening OP (also referred to as “contact opening”) having a diameter W1 to expose the upper surface of the semiconductor structure layer 11 (in other words, the upper surface of the p-contact layer 19). More specifically, a circular (cylindrical) opening OP having a central axis CZ and penetrating through the insulating film 21 is provided. The insulating film 21 functions as a current confinement layer.

The insulating film 21 also functions as a protective film and protects crystal layers constituting the PCSEL element 10 and containing aluminum (Al) from corrosive gas and the like. Moreover, the insulating film 21 prevents adhered objects, short circuits due to solder creeping during mounting, and the like, thereby contributing to improvement of reliability and yield. The material of the insulating film 21 is not limited to SiO₂ and may be selected from ZrO₂, HfO₂, TiO₂, Al₂O₃, SiNx, Si, and the like.

The p electrode 23 (also referred to as “contact electrode”), which makes ohmic contact with the p-contact layer 19, is provided on the p-contact layer 19 exposed through the contact opening OP.

More specifically, the p electrode 23 is formed so as to fill the circular opening OP as a current injection region 23R. In other words, the p electrode 23 has a circular shape with the central axis CZ along an axis (z direction) passing through the center of the p electrode 23 and orthogonal to the air-hole layer 14P in a top view.

The p electrode 23 is filled such that its upper surface is flat and parallel to the air-hole layer 14P. As illustrated in FIG. 1A, the p electrode 23 is preferably formed so as to fill the opening OP, overlap the insulating film 21, and have a flat surface upper surface. This makes it possible to more accurately form a flat light-reflecting layer 24 and to emit reflected diffracted light Lr as light that is substantially parallel to directly diffracted light Lr. Note that the upper surface of the p electrode 23 may be formed so as to flush with the upper surface of an insulating layer 21. In other words, the p electrode 23 may fill the opening OP such that the upper surface of the p electrode 23 and the upper surface of the insulating layer 21 are on the same plane.

The p electrode 23 is preferably formed of a light-transmissive electric conductor, and is formed of, for example, indium tin oxide (ITO). Its layer thickness is 135 nm.

Note that the p electrode 23 is not limited to ITO, but a light-transmissive electric conductor such as zinc tin oxide (ZTO), GZO (ZnO:Ga), or AZO (ZnO:Al) may be used.

Note that the diameter W1 of the formation region (in other words, the current injection region 23R) of the p electrode 23 is 300 μm. The thickness of the p electrode 23 may be selected as appropriate within a range of 20 nm to 300 nm, and is 135 nm in the embodiment.

A silver alloy (Ag alloy) layer as the light-reflecting layer 24 is provided on the p electrode 23. The light-reflecting layer 24 is provided so as to cover at least the entirety of the opening OP in a top view. The light-reflecting layer 24 has a flat surface parallel to the air-hole layer 14P.

The light-reflecting layer 24 is made of a silver alloy (Ag alloy) and has a layer thickness of, for example, 150 nm. In addition to an Ag alloy, materials such as Al, Al alloy, and a dielectric distributed Bragg reflector (DBR) may be used as the light-reflecting layer 24.

A thermal conductivity adjustment layer 31 is formed on the light-reflecting layer 24. The thermal conductivity adjustment layer 31 is constituted by a layer including at least one material selected from materials having a thermal conductivity lower than the effective thermal conductivity of at least semiconductor layers provided on the active layer 15, in other words, semiconductor layers (in other words, the second semiconductor layer 11A) between the active layer 15 and the p electrode 23.

Note that, in a case where the second semiconductor layer 11A is made of a gallium nitride (GaN)-based semiconductor, the thermal conductivity adjustment layer 31 is preferably formed to include a material having a thermal conductivity lower than that of GaN. In the present embodiment, the thermal conductivity adjustment layer 31 is formed of a material having a thermal conductivity lower than that of GaN.

For example, oxides such as SiO₂, Al₂O₃, Ta₂O₅, ZrO₂, and HfO₂, nitrides such as SiNx, oxynitrides such as SiON and ALON, conductive oxide films such as ITO, AZO, and GZO, and metals such as Ti, V, and Pt may be selected as the thermal conductivity adjustment layer 31.

A pad electrode 32 is provided on the light-reflecting layer 24 so as to cover the entirety of the thermal conductivity adjustment layer 31 and bury the thermal conductivity adjustment layer 31. As described above, the thermal conductivity adjustment layer 31 is provided in contact with the light-reflecting layer 24.

The pad electrode 32 is made of, for example, a Ni/Pd/Au layer in which nickel (with a layer thickness of 10 nm), palladium (with a layer thickness of 200 nm), and gold (with a layer thickness of 800 nm) are deposited in the stated order.

Note that Ni/Au, platinum/gold (Pt/Au), Pt/Pd/Au, titanium/gold (Ti/Au), Ti/Pt/Au, tungsten/palladium/gold (W/Pd/Au), W/Au, W/Pt/Au, and the like may be used as the pad electrode 32.

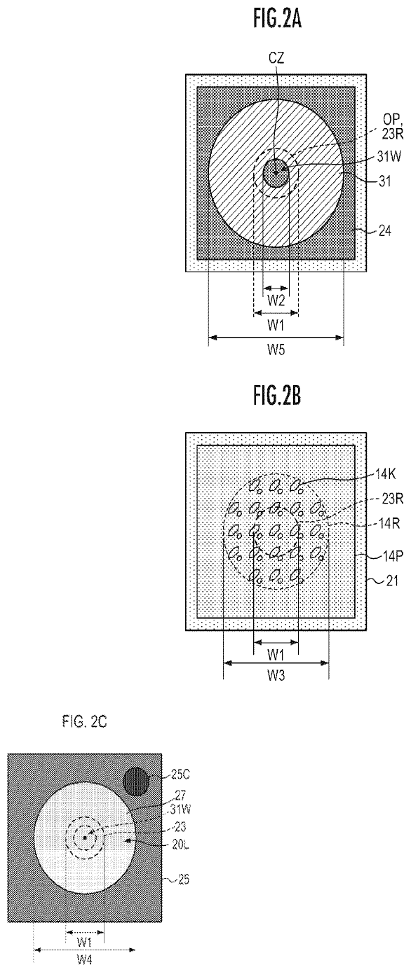

An n electrode 25 (cathode) having a circular opening (in FIG. 2C, the light emission region 20L) is formed on the back surface of the substrate 12. In addition, an antireflection (AR) coating layer 27 is formed in a region inside the n electrode 25.

The n electrode 25 is made of Ti/Pt/Au and in ohmic contact with the substrate 12. The electrode material may be selected from Ti/Al, Ti/Rh, Ti/Al/Pt/Au, Ti/Au, vanadium/aluminum (V/Al), V/Rh, V/Al/Pt/Au, V/Pt/Au, and the like instead of Ti/Pu/Au.

Emitted light from the active layer 15 is diffracted by the air-hole layer (PC layer) 14P. Light (directly diffracted light Ld: first diffracted light) diffracted by the air-hole layer 14P and directly emitted from the air-hole layer 14P and light (reflected diffracted light Lr: second diffracted light) emitted through diffraction by the air-hole layer 14P and reflected by the light-reflecting layer 24 are emitted to outside from the light emission region 20L (FIG. 2C) on a back surface (emission surface) 12R of the substrate 12.

FIG. 2A is a plan view schematically illustrating the upper surface of the PCSEL element 10. Note that, for clarity and ease of understanding of the diagram, the upper surface from which the pad electrode 32 is removed is schematically illustrated.

FIG. 2B is a cross-sectional view schematically illustrating a section of the air-hole layer 14P along a plane parallel to the n-side guide layer 14, and FIG. 2C is a plan view schematically illustrating the lower surface of the PCSEL element 10.

As illustrated in FIG. 2A, the thermal conductivity adjustment layer 31 has a circular annular plate shape that has a center at (is coaxial with) the central axis of the p electrode 23, in other words, the central axis CZ of the current injection region 23R. More specifically, the thermal conductivity adjustment layer 31 has a circular opening 31W (also referred to as “thermal conductivity adjustment opening”) in a top view, and an opening diameter (diameter) W2 of the opening 31W is smaller than the diameter W1 of the p electrode 23 (current injection region 23R) (W2<W1). In other words, the thermal conductivity adjustment opening 31W has a similar shape with a radius smaller than that of the contact opening OP. From the viewpoint of enabling two-dimensional uniform adjustment of heat generation distribution, the thermal conductivity adjustment opening 31W preferably has a shape similar to that of the contact opening OP. The thermal conductivity adjustment layer 31 has an outer diameter W5.

As illustrated in FIG. 2B, for example, the air holes 14K in the air-hole layer 14P are periodically arrayed in an air-hole formation region 14R having a circular shape at a section. A diameter W3 of the air-hole formation region 14R is equal to or larger than the diameter W1 of the current injection region 23R when viewed in a direction (z direction) orthogonal to the air-hole layer 14P (in a top view) (W1≤W3). Note that the shape of the air-hole formation region 14R is not limited to a circular shape. The shape only needs to have sizes enough to contain at least the current injection region 23R in a top view.

As illustrated in FIG. 2C, the n electrode 25 (cathode) is formed with a circular opening outside the air-hole formation region 14R so as not to overlap the air-hole formation region 14R when viewed in a direction orthogonal to the air-hole layer 14P.

The opening of the n electrode 25 has a diameter W4, and the diameter W4 of the opening is larger than the diameter W1 of the current injection region 23R (W1<W4).

A bonding pad 25C to be connected to a power supply wire is provided on the n electrode 25.

### (b) Photonic Crystal Layer (Air-Hole Layer)

As illustrated in FIGS. 1A and 1B, the air-hole layer 14P includes regularly arrayed air holes that resonance light emitted from the active layer 15 in a horizontal plane.

FIG. 3 is a diagram schematically illustrating an example of the air-hole array in a plane parallel to the air-hole layer 14P. Specifically, FIG. 3 is a plan view schematically illustrating air hole pairs 14K (also simply referred to as air holes 14K) of a main air hole 14K1 and a sub air hole 14K2, which are arrayed in a square lattice pattern in the plane of the air-hole layer 14P, when viewed from top.

In other words, the air-hole layer 14P has a double-lattice structure. Note that the main air holes 14K1 and the sub air holes 14K2 (air holes 14K) are hatched for the clarity of the drawing.

More specifically, the main air holes 14K1 are arrayed with their centroids CD1 in a square lattice pattern with a period (lattice constant) PK in two directions (x direction and y direction) orthogonal to each other. Similarly, the sub air holes 14K2 are arrayed with their centroids CD2 in a square lattice pattern with the period PK in the x and y directions. Note that the period PK of the air holes 14K may be adjusted in accordance with a desired oscillation wavelength.

Each main air hole 14K1 has an elongated hexagonal shape surrounded by m-planes, which are {10-10} planes, in a top view (in other words, when viewed in the direction orthogonal to the air-hole layer 14P). Each sub air hole 14K2 also has a shape surrounded by m-planes.

Note that the x and y directions are directions tilted by 45° with respect to the longitudinal direction (<11-20> direction) and the lateral direction (<1-100> direction) of the main air holes 14K1, respectively. In the present specification, x-y coordinates are also referred to as air-hole coordinates.

The centroid CD2 of each sub air hole 14K2 is apart from the centroid CD1 of the corresponding main air hole 14K1 by Δx in the x direction and Δy in the y direction. In this example, Δx=Δy=0.46 PK is set. In other words, the centroid CD2 of each sub air hole 14K2 is apart in the <1-100> direction from the centroid CD1 of the corresponding main air hole 14K1.

The inter-centroid distance Δx in the x direction and the inter-centroid distance Δy in the y direction can be adjusted as appropriate in accordance with laser characteristics such as a current value required for a device to which the laser element is applied, and slope efficiency of the laser emission intensity.

Note that description is made of an example in which the air-hole layer 14P has a double-lattice structure, but the present invention is not limited thereto. The air-hole layer 14P may have a single-lattice structure or a multiple-lattice structure.

### 2. PCSEL Element Manufacturing Method

Manufacturing steps S1 to S9 of a method for manufacturing the PCSEL element 10 will be sequentially described below.

### (S1) Crystal Growth

A metalorganic vapor phase epitaxy (MOVPE) device was used to grow an n-Al_{0.04}Ga_{0.96}N layer serving as the n-clad layer 13 to a thickness of 2 μm on the +c-plane GaN substrate 12. Subsequently, an n-GaN layer was grown to a thickness of 500 nm on the n-clad layer 13.

### (S2) Hole Formation

A SiNx film having a thickness of approximately 100 nm was deposited on the grown n-GaN layer by using a plasma CVD method. Subsequently, an electron beam resist was applied onto the SiNx film by spin coating and the substrate was placed in an electron beam lithography device (EB device) to form a two-dimensional periodic pattern corresponding to the above-described two-dimensional photonic crystal structure.

After the patterned resist was developed, the SiNx was selectively dry-etched by using an inductively coupled plasma reactive ion etching (ICP-RIE) device. Accordingly, openings arrayed in a square lattice pattern were formed so as to penetrate through the SiNx film.

Thereafter, the resist was removed and the SiNx was used as a hard mask to dry-etch the n-GaN layer with an ICP-RIE device using Cl₂, BCl₃, and Ar gasses. Accordingly, holes arrayed in a square lattice pattern are formed in the n-GaN layer. The etching depth in this case was approximately 190 nm. Thereafter, the SiNx hard mask was removed by using buffered hydrofluoric acid (BHF) .

### (S3) Crystal Regrowth

The substrate on which the photonic crystal was formed was placed in the MOVPE device again and subjected to embedment growth so as to leave the holes, thereby forming the air holes 14K. Specifically, undoped GaN and undoped InGaN were grown to thicknesses of 70 nm and 50 nm, respectively, to form the embedding layer 14B. Accordingly, the n-side guide layer 14 including the air-hole layer 14P was formed.

Note that, through the embedment growth, the main air holes 14K1 and the sub air holes 14K2 of the air-hole layer 14P each have a hexagonal shape surrounded by m-planes, which are {10-10} planes, in a top view. The depths of the main air holes 14K1 and the sub air holes 14K2 in the air-hole layer 14P were 90 nm and 70 nm, respectively.

Subsequently, the active layer 15 (MQW layer) made of two pairs of InGaN/GaN quantum wells was grown on the embedding layer 14B (in other words, on the n-side guide layer 14). Subsequently, undoped InGaN and undoped GaN were grown to thicknesses of 70 nm and 180 nm, respectively, on the active layer 15 to form the p-side guide layer 16.

Subsequently, the electron blocking layer 17 made of p-AlGaN was grown to a thickness of 15 nm, and the p-clad layer 18 made of a p-AlGaN layer was grown to a thickness of 300 nm on the electron blocking layer 17. Subsequently, the p-contact layer 19 made of a p-GaN/p-InGaN layer was grown to a thickness of 25 nm.

### (S4) Formation of Electrode and Light-Reflecting Layer

First, separation grooves for separating individual PCSEL elements 10 were formed in the grown wafer by using a dry-etching device. The separation grooves were formed to a depth reaching the interior of the substrate 12.

Subsequently, a SiO₂ film having thickness of 100 nm was deposited on the wafer by a sputtering method. After the deposition, the SiO₂ film was removed by photolithography with BHF and patterned. Accordingly, the insulating film 21 having the opening OP having a diameter of 300 μm and corresponding to the current injection region 23R was formed.

Subsequently, an ITO film (with a layer thickness of 135 nm) was deposited to form the p electrode 23 that fills the opening OP. Note that the p electrode 23 was formed so as to fill the opening OP and cover the insulating film 21.

Thereafter, an Ag alloy having a thickness of 150 nm was deposited on the p electrode 23 to form the light-reflecting layer 24.

### (S5) Formation of Thermal Conductivity Adjustment Layer

Subsequently, the circular annular thermal conductivity adjustment layer 31 made of a SiO₂ film and having the circular opening 31W was formed on the light-reflecting layer 24. The thermal conductivity adjustment layer 31 had a film thickness of 25 nm and an opening diameter W2 of 160 nm.

### (S6) Formation of Pad Electrode

The pad electrode 32 that buries the thermal conductivity adjustment layer 31 was formed by sequentially depositing Ni, Pd, and Au having thicknesses of 10 nm, 200 nm, and 800 nm, respectively, on the thermal conductivity adjustment layer 31.

### (S7) Formation of Back Surface Electrode

Subsequently, the back surface of the substrate 12 was polished and then mirrored finishing was performed by chemical machine polishing (CMP) to obtain a wafer with a thickness of 170 nm. Subsequently, Ti, Pt, and Au (with layer thicknesses of 50 nm, 50 nm, and 500 nm, respectively) were deposited on the polished surface to form the n electrode 25 (cathode electrode).

In addition, SiNₓ and SiO₂ (with layer thicknesses of 32 nm and 53 nm, respectively) were deposited on the substrate back surface in the opening region (in other words, the light emission region 20L) of the n electrode 25 to form an antireflection coating layer 27 that is a reflection prevention layer.

### (S9) Dicing

Finally, scribing was performed by using a laser scribing device or a diamond scribing device, and the wafer was diced by cleaving with a cleaving device, thereby obtaining PCSEL elements 10.

### 3. Mounting of PCSEL Element

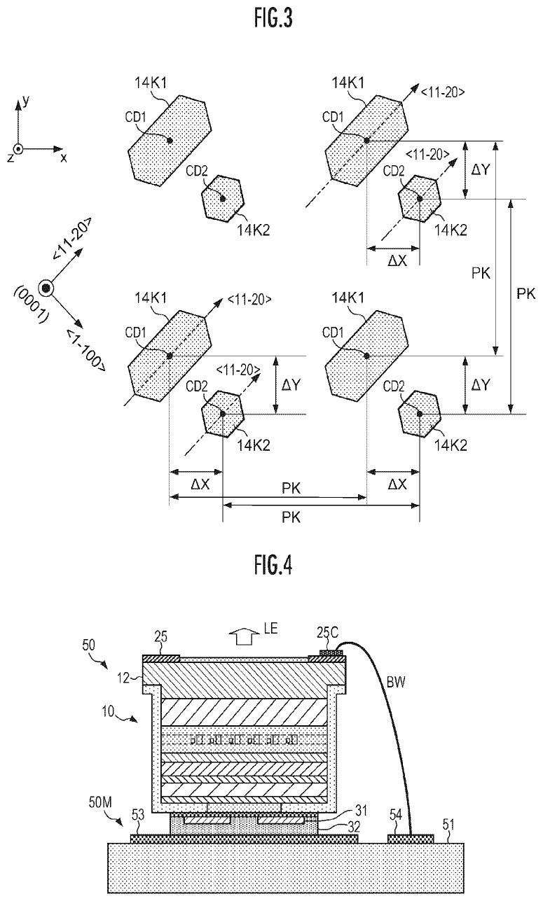

FIG. 4 is a cross-sectional view illustrating a surface-emitting laser device 50 constituted by the PCSEL element 10 mounted on a submount 50M. Note that a section including the central axis CZ of the p electrode 23 (current injection region 23R) is illustrated.

In the surface-emitting laser device 50, the PCSEL element 10 is mounted on the submount 50M by bonding with solder. The submount 50M includes a base material 51, and an anode wire 53 and a cathode wire 54 that are provided on the base material 51.

Specifically, the PCSEL element 10 is electrically connected by junction-down bonding (epi-down bonding) with the pad electrode 32 bonded to the anode wire 53. The n electrode 25 (bonding pad 25C) of the PCSEL element 10 and the cathode wire 54 are connected to each other through a bonding wire BW that is a gold wire.

Note that the submount 50M using diamond as the base material 51 is used in the embodiment. Note that, in addition to diamond, materials having high thermal conductivity, such as aluminum nitride (AlN), silicon carbide (SiC), graphite, copper tungsten (CuW), Cu, and Ag-diamond are suitable as the base material of the submount 50M.

In addition, a heat sink is attached to the back surface of the submount 50M on which the PCSEL element 10 is mounted.

Light from the PCSEL element 10 is emitted from the back surface side of the substrate 12 (in the drawing, emitted light LE).

### 4. Characteristic Evaluation of PCSEL Element

### (a) Temperature Distribution in Air-Hole Layer

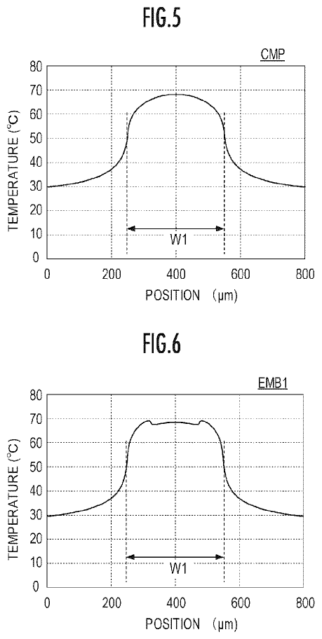

first, influence of temperature distribution in the air-hole layer will be discussed. FIG. 5 illustrates a calculation result of finite element analysis of temperature distribution in the air-hole layer. More specifically, FIG. 5 is a graph illustrating, as a comparative example (CMP), temperature distribution in the air-hole layer of a PCSEL element in which the thermal conductivity adjustment layer 31 is not provided.

Note that the PCSEL element according to the comparative example (CMP) is different from the PCSEL element 10 according to the first embodiment in that the thermal conductivity adjustment layer 31 is not provided, whereas the other configuration is the same. FIG. 5 illustrates temperature distribution in the air-hole layer of a surface-emitting laser device on which the PCSEL element according to the comparative example is mounted.

FIG. 5 illustrates the calculation result in a case where 24 W of electric power was injected. In the drawing, dashed lines indicate a current injection region (W1=300 μm). In the comparative example not including the thermal conductivity adjustment layer 31, the temperature distribution has a shape that is convex toward the upper side with a peak at the center of the current injection region.

Temperature is 68.2° C. at the center peak and 51.2° C. at outer peripheral parts of the current injection region. Since the refractive index varies in accordance with this temperature distribution, the resonance wavelength varies in accordance with the shape of the temperature distribution.

According to research by the inventors, CW oscillation is possible even when temperature distribution as in the comparative example occurs (refer to Non Patent Literature 2), but the laser efficiency decreases due to reduction in a region (resonator length) in which coherent resonance is possible. The efficiency decrease is caused by increase in area that does not contribute to oscillation and in-plane light leakage due to reduction in the resonator length.

When 24 W of electric power was applied, an effective oscillation region (in other words, the resonator length of coherent operation) was approximately 195 μm for the current injection region of 300 μm. Converting the resonator length (region) into a temperature difference indicates that coherent oscillation is possible within a temperature difference of approximately 4° C.

### (b) Temperature Distribution in Air-Hole Layer According to First Embodiment

FIG. 6 illustrates a calculation result of temperature distribution in the air-hole layer 14P for the PCSEL element 10 (EMB1) according to the first embodiment described above. Note that, as in the case of the comparative example, temperature distribution in the air-hole layer 14P of the PCSEL element 10 in the surface-emitting laser device 50 (FIG. 4) on which the PCSEL element 10 is mounted is illustrated. Similarly, the calculation result corresponds to a case where 24 W of electric power is applied.

As described above, in the PCSEL element 10 (EMB1), the thermal conductivity adjustment layer 31 has the opening 31W with the opening diameter W2 smaller than the diameter W1 of the current injection region 23R.

As illustrated in FIG. 6, it can be understood that temperature distribution in the air-hole layer 14P of the PCSEL element 10 (EMB1) is flat as compared to that of the comparative example. Specifically, based on the criterion that coherent oscillation is possible within a temperature difference of 4° C., the diameter of the effective oscillation region was 256 μm for the current injection region of 300 μm. In other words, it was found that the effective oscillation region is increased by 31% in diameter and by 72% in area as compared to the comparative example.

Such an effect occurs for the first time when the opening diameter W2 of the opening 31W of the thermal conductivity adjustment layer 31 is made smaller than the diameter W1 of the current injection region 23R (W2<W1). This is because, in the case of junction-down bonding in which the p semiconductor side is bonded to a heat sink to enhance heat dissipation, the distance between the active layer and the heat sink is extremely short, and most of heat dissipation is contributed by heat dissipation to the heat sink side.

Accordingly, the light emission efficiency during continuous wave (CW) drive improves. Moreover, a surface-emitting laser with excellent oscillation stability such as single-mode stability can be provided.

### Second Embodiment

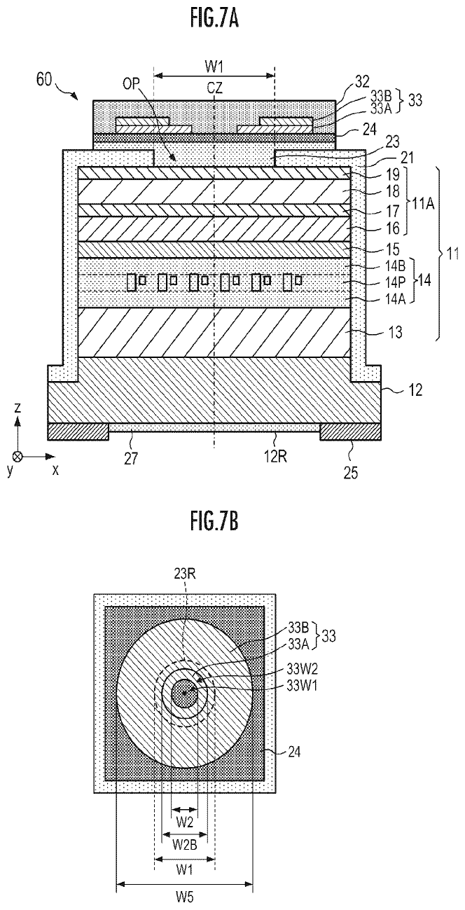

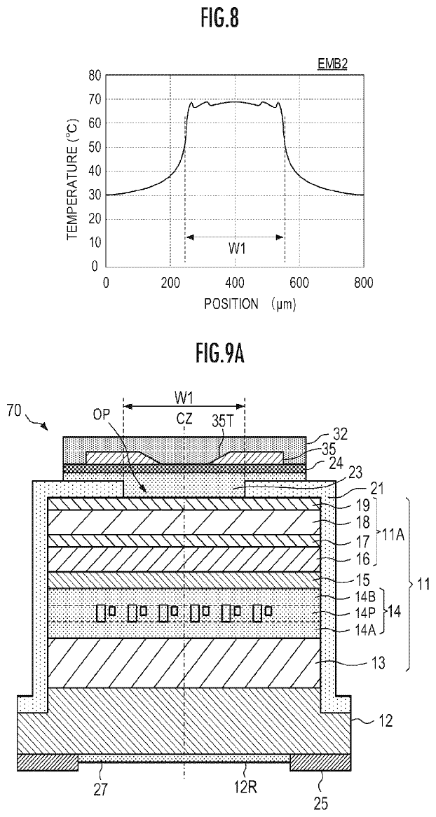

FIG. 7A is a cross-sectional view schematically illustrating an example of the structure of a PCSEL element 60 (EMB2) according to a second embodiment. Note that a section including the central axis CZ of the p electrode 23 (current injection region 23R) is illustrated. FIG. 7B is a plan view schematically illustrating the upper surface of the PCSEL element 60. Note that the upper surface from which the pad electrode 32 is removed is schematically illustrated.

### (a) Element Structure

The PCSEL element 60 (EMB2) is different from the PCSEL element 10 according to the first embodiment in that the PCSEL element 60 (EMB2) includes a thermal conductivity adjustment layer 33 of a double-layer structure, whereas the other configuration is the same.

More specifically, as illustrated in FIG. 7B, the thermal conductivity adjustment layer 33 has a circular annular shape and has a double-layer structure in which a first low thermal conductivity layer 33A having a circular opening 33W1 with the opening diameter W2 and a second low thermal conductivity layer 33B having a circular annular shape and having a circular opening 33W2 with an opening diameter W2B (>W2) are stacked.

In other words, the thermal conductivity adjustment layer 33 of a double-layer structure has the opening 33W1 with the opening diameter W2, and the diameter W1 of the current injection region 23R (p electrode 23) and the opening diameters W2 and W2B of the first and second low thermal conductivity layers 33A and 33B satisfy W2<W2B<W1.

The first low thermal conductivity layer 33A and the second low thermal conductivity layer 33B are placed over such that their central axes are coaxial with each other, and are provided such that the central axes of the first low thermal conductivity layer 33A and the second low thermal conductivity layer 33B are coaxial with the central axis CZ of the p electrode 23 (current injection region 23R).

The first low thermal conductivity layer 33A and the second low thermal conductivity layer 33B are formed of SiO₂ films, and for example, the first low thermal conductivity layer 33A has a thickness of 20 nm, and the second low thermal conductivity layer 33B has a thickness of 100 nm.

### (b) Temperature Distribution in Air-Hole Layer

FIG. 8 illustrates a calculation result of temperature distribution in the air-hole layer 14P for the PCSEL element 60 (EMB2). Note that, as in the case of the PCSEL element 10 (EMB1) according to the first embodiment, temperature distribution in the air-hole layer 14P of the surface-emitting laser device (refer to FIG. 4) in which the PCSEL element 60 is mounted on the submount 50M is illustrated. Similarly, the calculation result corresponds to a case where 24 W of electric power is applied.

Note that calculation was performed with W2=160 μm, W2B=260 μm, and W1=300 μm.

As illustrated in FIG. 8, it can be understood that the temperature distribution is further flattened as compared to the PCSEL element 10 (EMB1). Specifically, based on the criterion that coherent oscillation is possible with a temperature difference of 4° C., the diameter of the effective oscillation region was 290 μm for the current injection region of 300 μm.

Accordingly, it was found that the effective oscillation region is increased by 49% in diameter and by 121% in area as compared to the comparative example (CMP) for which the diameter of the effective oscillation region was 195 μm.

Thus, the light emission efficiency during continuous wave (CW) drive largely improves as compared to the comparative example (CMP) and the PCSEL element 10 (EMB1) according to the first embodiment, and a surface-emitting laser with excellent oscillation stability such as single-mode stability can be provided.

Note that the above description is made of the case where the thermal conductivity adjustment layer 33 has a double-layer structure, but the thermal conductivity adjustment layer 33 may be formed as a stepped thermal conductivity adjustment layer including an outer peripheral portion (corresponding to the second low thermal conductivity layer 33B) and an inner peripheral portion having a circular annular shape and a layer thickness smaller than the outer peripheral portion.

### Third Embodiment

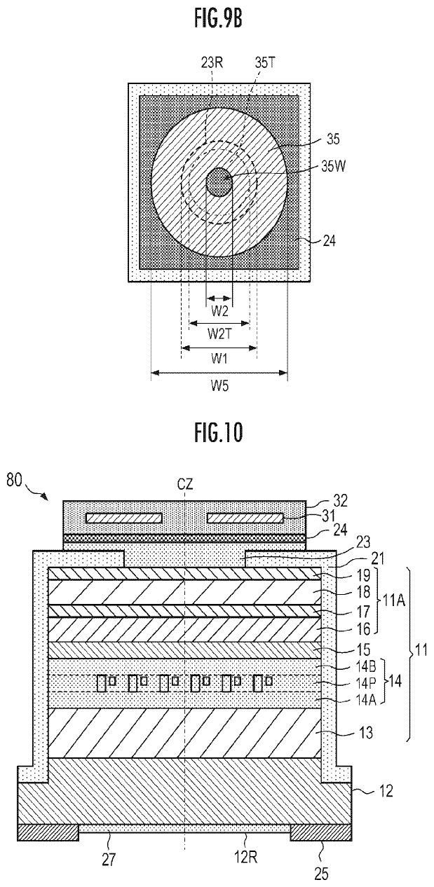

FIG. 9A is a cross-sectional view schematically illustrating an example of the structure of a PCSEL element 70 (EMB3) according to a third embodiment, in a similar manner to FIGS. 1A and 7A. FIG. 9B is a plan view schematically illustrating the upper surface of the PCSEL element 70. Note that the upper surface from which the pad electrode 32 is removed is schematically illustrated.

The PCSEL element 70 according to the present embodiment is different from the PCSEL element 10 according to the first embodiment in that a thermal conductivity adjustment layer 35 includes a tilted circular annular inner peripheral portion 35T having a layer thickness that decreases in a tapered shape toward the center of a thermal conductivity adjustment opening 35W. The other configuration is the same as that of the PCSEL element 10 according to the first embodiment.

More specifically, the thermal conductivity adjustment layer 33 has a circular annular shape and has a circular opening 35W with the opening diameter W2. The circular annular inner peripheral portion 35T has an outer diameter W2T. The diameter W1 of the current injection region 23R and the thermal conductivity adjustment opening 35W of the thermal conductivity adjustment layer 33 satisfy W2<W1.

Note that the outer diameter W2T of the inner peripheral portion 35T preferably satisfies W2T<W1 but is not limited thereto. Specifically, the layer thickness only needs to decrease toward the center within the range of the diameter W1 of the current injection region 23R, and W2T≥W1 may be satisfied.

### Fourth Embodiment

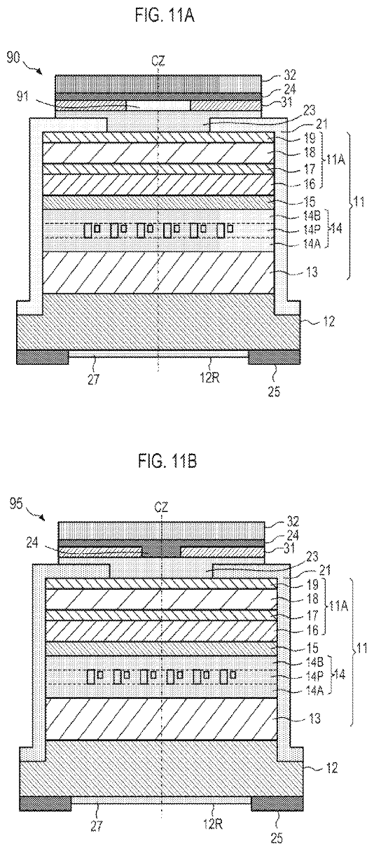

FIG. 10 is a cross-sectional view schematically illustrating an example of the structure of a PCSEL element 80 (EMB4) according to a fourth embodiment.

In the PCSEL element 10 according to the first embodiment, the thermal conductivity adjustment layer 31 is provided on the light-reflecting layer 24, but in the PCSEL element 80 according to the present embodiment, the thermal conductivity adjustment layer 31 is entirely buried inside the pad electrode 32 and formed apart from the p electrode.

In other words, the thermal conductivity adjustment layer 31 may be formed apart from the p electrode 23 (contact electrode). The heat equalization effect can be adjusted by selecting the separation distance.

### Fifth Embodiment

FIG. 11A is a cross-sectional view schematically illustrating an example of the structure of a PCSEL element 90 (EMB5) according to a fifth embodiment. FIG. 11B is a cross-sectional view schematically illustrating an example of the structure of a PCSEL element 95 as a modification of the fifth embodiment.

In the PCSEL element 90 according to the present embodiment, the thermal conductivity adjustment layer 31 is provided below and in contact with the light-reflecting layer 24. More specifically, the thermal conductivity adjustment layer 31 is provided on the p electrode 23 such that an opening part of the thermal conductivity adjustment layer 31 is positioned on the central axis CZ. The opening part is embedded by a light-transmissive electric conductor 91, and the upper surfaces of the thermal conductivity adjustment layer 31 and the light-transmissive electric conductor 91 are flat. The upper surfaces of the thermal conductivity adjustment layer 31 and the light-transmissive electric conductor 91 are preferably flush surfaces that are continuously flat. The light-reflecting layer 24 is provided on the thermal conductivity adjustment layer 31 and the light-transmissive electric conductor 91, and the pad electrode 32 is formed on the upper surface of the light-reflecting layer 24. It is preferable to use materials with a small refractive index difference between the light-transmissive electric conductor 91 and the thermal conductivity adjustment layer 31. For example, ITO may be used for the light-transmissive electric conductor 91, and SiN may be used for the thermal conductivity adjustment layer 31. Note that, as illustrated in FIG. 11B, the opening part may be embedded by the light-reflecting layer 24. In this case, the upper surface of the light-reflecting layer 24 is flat. Specifically, the light-transmissive electric conductor 91 may not be formed at the opening part, and instead of the light-transmissive electric conductor 91, the light-reflecting layer 24 may be formed on the opening part and the upper surface of the thermal conductivity adjustment layer 31 such that the upper surface of the light-reflecting layer 24 is flat.

In the PCSEL element 90, since the thermal conductivity adjustment layer 31 is provided in contact with the p electrode 23 (contact electrode), a higher heat equalization effect can be achieved.

### Sixth Embodiment

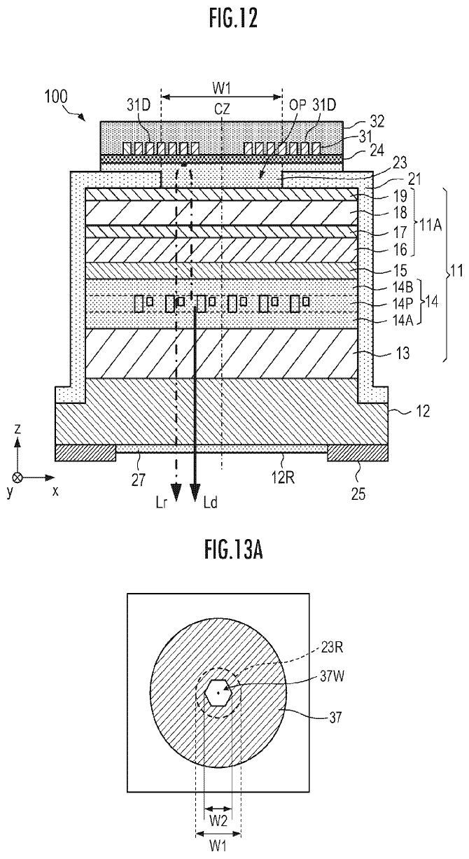

FIG. 12 is a cross-sectional view schematically illustrating an example of the structure of a PCSEL element 100 (EMB6) according to a sixth embodiment.

In the PCSEL element 100 according to the present embodiment, the thermal conductivity adjustment layer 31 is constituted by a layer formed with a dot pattern 31D. The dot pattern 31D is formed of the same material as that of the thermal conductivity adjustment layer 31 and constituted by, for example, a layer in which SiO₂ is formed in a dot pattern. The dot pattern 31D may be a periodic or non-periodic pattern but preferably has a shape that the spacing between dots becomes denser as the distance from the central axis CZ increases. With the structure in which the spacing between dots becomes denser as the distance from the central axis CZ increases, a higher heat equalization effect can be achieved.

### Modifications

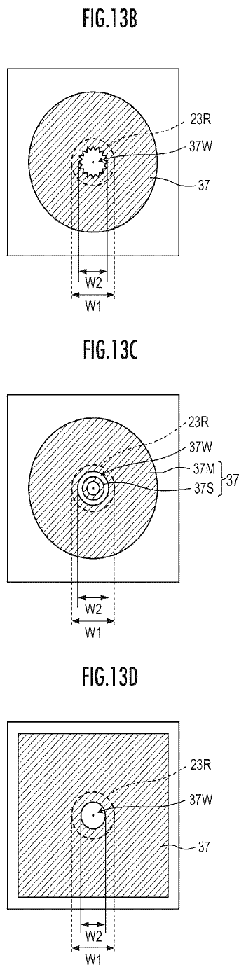

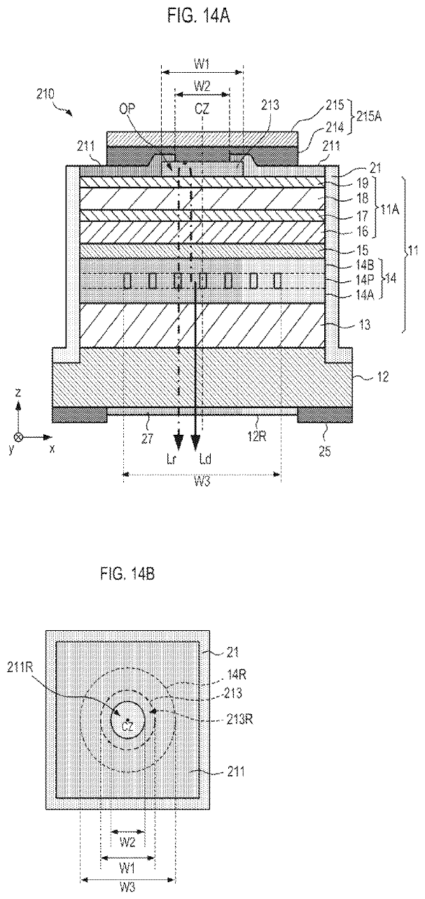

FIG. 13A is a top view schematically illustrating Modification 1 of the thermal conductivity adjustment layer according to the first to fifth embodiments described above. A thermal conductivity adjustment layer 37 according to Modification 1 has a polygonal opening 37W (thermal conductivity adjustment opening).

In Modification 1, the opening diameter of the opening 37W is defined as the diameter (or major radius) of a circle (including an ellipse) that the opening 37W circumscribes, which is the opening diameter W2. The opening diameter W2 and the diameter W1 of the current injection region 23R (p electrode 23) (in other words, the opening diameter of the contact opening) satisfy W2<W1. Note that the opening 37W preferably has a regular polygon shape.

FIG. 13B is a top view schematically illustrating Modification 2 of the thermal conductivity adjustment layer according to the above-described embodiments. The thermal conductivity adjustment layer 37 according to Modification 2 has the opening 37W in a gear shape.

In Modification 2, the opening diameter of the opening 37W is defined as the diameter of a circle that the opening 37W circumscribes, which is the opening diameter W2. The opening diameter W2 and the diameter W1 of the current injection region 23R satisfy W2<W1.

FIG. 13C is a top view schematically illustrating Modification 3 of the thermal conductivity adjustment layer according to the above-described embodiments. The thermal conductivity adjustment layer 37 according to Modification 2 has a double-ring shape. More specifically, the thermal conductivity adjustment layer 37 includes a first thermal conductivity adjustment layer 37M and a ring-shaped second thermal conductivity adjustment layer 37S provided inside the first thermal conductivity adjustment layer 37M.

In Modification 3, the first thermal conductivity adjustment layer 37M has the opening 37W in a circular shape, and the opening 37W has the opening diameter W2. The opening diameter W2 and the diameter W1 of the current injection region 23R satisfy W2<W1.

FIG. 13D is a top view schematically illustrating Modification 4 of the thermal conductivity adjustment layer according to the above-described embodiments. Modification 4 is different from the thermal conductivity adjustment layer according to the above-described embodiments in that the thermal conductivity adjustment layer 37 has a quadrilateral outer shape, whereas the other configuration is the same as that of the thermal conductivity adjustment layer according to the above-described embodiments.

In Modification 4, the thermal conductivity adjustment layer 37 has the opening 37W in a circular shape, and the opening 37W has the opening diameter W2. The opening diameter W2 and the diameter W1 of the current injection region 23R satisfy W2<W1.

The embodiments of the present invention are described above in detail. Note that, in the above-described embodiments, the shapes of the contact opening and thermal conductivity adjustment opening are preferably circular, but not limited thereto. The openings may have, for example, elliptical, polygonal, gear shapes but are preferably rotationally symmetric with respect to the central axis. In these cases, each opening diameter is defined as the diameter (or major radius) of a circle (including an ellipse) that the opening shape circumscribes.

The thermal conductivity adjustment opening preferably has a shape similar to the contact opening.

As described above, according to the present invention, it is possible to provide a photonic-crystal surface-emitting laser in which temperature distribution in a photonic crystal can be easily flattened during continuous wave (CW) drive, thereby improving light emission efficiency and achieving excellent oscillation stability.

### Seventh Embodiment

### (1) Element Structure

FIG. 14A is a cross-sectional view schematically illustrating the structure of a PCSEL element 210 according to a seventh embodiment. Note that a section including the central axis CZ of a p electrode 213 is illustrated. FIG. 14B is a plan view schematically illustrating the upper surface of the PCSEL element 210. Note that the upper surface from which a pad electrode 215 and a light-reflecting layer 214 are removed is schematically illustrated.

Although description will be made of a case where the air-hole layer 14P has a single-lattice structure, the air-hole layer 14P may have a multiple-lattice structure.

In the PCSEL element 210 according to the present embodiment, the light-transmissive p electrode 213 (p contact electrode) is formed on the p-contact layer 19 in ohmic contact. Specifically, a region in which the p electrode 213 contacts the p-contact layer 19 is a contact region and also a current injection region 213R.

The p electrode 213 has a thin cylindrical shape (central axis CZ), and a thermal conductivity adjustment layer 211 is formed so as to overlap an outer peripheral portion of the p electrode 213 and partially cover the upper surface of the outer peripheral portion.

More specifically, the p electrode 213 is formed of indium tin oxide (ITO) that is light-transmissive. Note that the p electrode 213 is preferably a light-transmissive electric conductor. In this case, the p electrode 213 is not limited to ITO, but a light-transmissive electric conductor such as zinc tin oxide (ZTO), GZO (ZnO:Ga), or AZO (ZnO:Al) may be used.

The p electrode 213 has the diameter W1 of 300 μm and a thickness of 135 nm. Note that the thickness of the p electrode 213 may be selected as appropriate within a range of 20 to 300 nm.

The thermal conductivity adjustment layer 211 is formed of a SiO₂ film having a thickness of 25 nm on the p electrode 213. As illustrated in FIG. 14B, the thermal conductivity adjustment layer 211 has an opening 211R (thermal conductivity adjustment opening) having a circular shape, in other words, a thin cylindrical shape having a central axis that is coaxial with the p electrode 213 (central axis CZ) in a top view, and having the diameter W2 smaller than the diameter W1 of the p electrode 213 (W2<W1). Moreover, the current injection region 213R is contained in the air-hole formation region 14R in a top view, and specifically, the diameter W1 of the current injection region 213R is smaller than the diameter W3 of the air-hole formation region 14R (W1<W3).

As in the cases of the above-described embodiments, the thermal conductivity adjustment layer 211 is constituted by a layer including at least one material selected from insulators and semiconductors having a thermal conductivity lower than at least the effective thermal conductivity of a semiconductor layer (second semiconductor layer) provided on the active layer 15. Moreover, as in the cases of the above-described embodiments, the thermal conductivity adjustment layer 211 is preferably formed to include a material having a thermal conductivity lower than that of GaN in a case where the second semiconductor layer 11A is made of a gallium nitride (GaN)-based semiconductor.

Oxides such as SiO₂, Al₂O₃, Ta₂O₅, ZrO₂, and HfO₂, nitrides such as SiNx, oxynitrides such as SiON and AlON, and metals such as Ti, V, and Pt may be selected as the thermal conductivity adjustment layer 211.

The p electrode 213 is exposed through the opening 211R of the thermal conductivity adjustment layer 211. A metal electrode 215A is provided on the p electrode 213 exposed through the thermal conductivity adjustment layer 211. The metal electrode 215A is formed in a range covering at least the entirety of the p electrode 213 in a top view.

The metal electrode 215A is constituted by the light-reflecting layer 214 and the pad electrode 215. The light-reflecting layer 214 is made of a silver alloy (Ag alloy) and has a layer thickness of, for example, 150 nm. In addition to an Ag alloy, materials such as Al, Al alloy, Rh, Ru, and dielectric DBR may be used as the light-reflecting layer 214.

The pad electrode 215 is provided on the light-reflecting layer 214. As the pad electrode 215, Ni, Pd, and Au having thicknesses of 10 nm, 200 nm, and 800 nm, respectively, were deposited. Note that the pad electrode 215 is preferably provided so as to cover the entire upper surface of the light-reflecting layer 214.

Note that the p electrode 213 and the thermal conductivity adjustment layer 211 may select any shapes such as circular shapes, polygonal shapes, gear shapes, and multiple-ring shapes in a top view (refer to FIGS. 13A to 13D, for example), but preferably have shapes that are rotationally symmetric with respect to the central axis CZ orthogonal to the air-hole layer 14P. The p electrode 213 and the thermal conductivity adjustment layer 211 further preferably have circular shapes to achieve two-dimensional uniform adjustment of temperature distribution.

The PCSEL element 210 was bonded on a submount made of diamond by soldering, and then mounted on the heat sink. Note that materials having high thermal conductivity, for example, AlN, SiC, graphite, CuW, Cu-diamond, and Ag-diamond may be used as the submount.

### (2) Element Evaluation

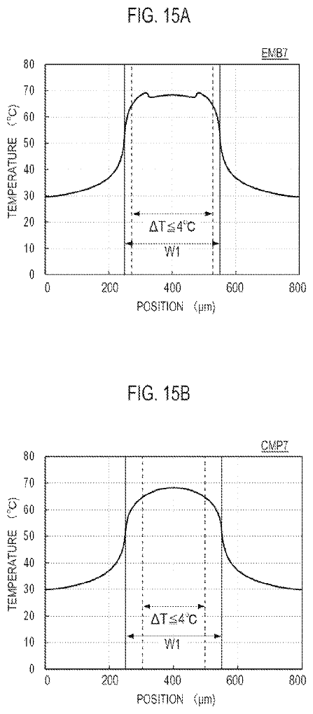

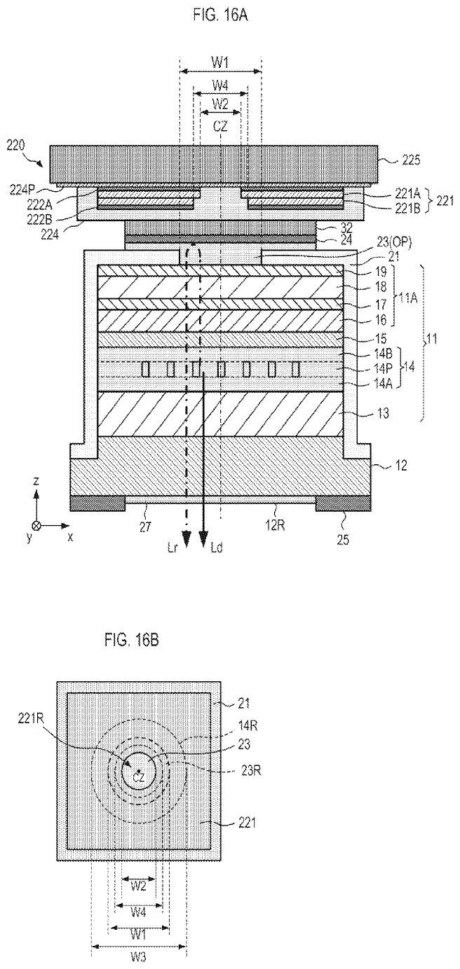

FIG. 15A is a graph illustrating a calculation result of finite element analysis of temperature distribution in the air-hole layer for the PCSEL element 210 (EMB7) according to the present embodiment. FIG. 15B is a graph illustrating, as a comparative example (CMP7), temperature distribution in the air-hole layer of a PCSEL element in which the thermal conductivity adjustment layer 211 is not provided.

Note that the horizontal axis represents the position in the air-hole layer 14P in a case where the central position of the current injection region 213R (diameter W1) is 400 μm (for an element size of 800 μm), and the vertical axis represents the temperature of the air-hole layer 14P.

As illustrated in FIGS. 15A and 15B, it can be understood that temperature distribution in the air-hole layer 14P of the PCSEL element 210 (EMB7) is flat as compared to that of the comparative example (CMP7). Specifically, as discussed in the above-described first embodiment, based on the criterion that coherent oscillation is possible with a temperature difference ΔT of 4°, the diameter of the effective oscillation region was 256 μm for the current injection region 213R (W1=300 μm) (ΔT≤4° C.). Accordingly, it was found that the effective oscillation region is increased by 31% in diameter and by 72% in area as compared to the diameter 195 μm of the effective oscillation region (ΔT≤4° C.) in the comparative example (CMP7).

Such an effect occurs for the first time when the diameter W2 of the opening 211R (thermal conductivity adjustment opening) of the thermal conductivity adjustment layer 211 is made smaller than the diameter W1 of the current injection region 213R (W2<W1). This is because, in the case of junction-down bonding in which the p semiconductor side is bonded to a submount (or support substrate) to enhance heat dissipation, the distance between the active layer and the submount is extremely short, and most of the heat dissipation is contributed by heat dissipation to the submount side. In other words, it is possible to flatten in-plane distribution of the resonance wavelength by compensating temperature distribution in an outer peripheral portion of the current injection region where the air-hole layer temperature largely decreases (refer to FIG. 15B) and the resonance wavelength largely changes.

Such degradation of oscillation characteristics due to temperature distribution is a problem unique to a PCSEL element in which light resonates in the in-plane direction of the air-hole layer and diffraction waves are radiated in the direction orthogonal to the air-hole layer.

Thus, with a thermal conductivity adjustment layer, it is possible to prevent increase in threshold current during continuous wave (CW) drive, thereby improving the light emission efficiency. Moreover, it is possible to provide a surface-emitting laser with excellent oscillation stability such as single-mode stability.

In addition, in the PCSEL element according to the present embodiment, the thermal conductivity adjustment layer 211 is formed so as to overlap the outer peripheral portion of the p electrode 213 (p contact electrode) and partially cover the upper surface of the outer peripheral portion, and thus the amount of current (electric field) that concentrates at end portions of the p electrode 213 and end portions of the active layer 15 can be reduced. The current concentration at the end portions would cause failure and degradation of the element, but with the PCSEL element according to the present embodiment, it is possible to improve element reliability and lifetime.

### Eighth Embodiment

### (1) Element Structure

FIG. 16A is a cross-sectional view schematically illustrating the structure of a PCSEL element 220 according to an eighth embodiment. FIG. 16B is a plan view schematically illustrating the upper surface of the PCSEL element 220. Note that FIG. 16B schematically illustrates a view from the upper surface of a thermal conductivity adjustment layer 221.

In the PCSEL element 220, the insulating film 21 formed on the upper surface of the semiconductor structure layer 11 is provided with an opening (contact opening) OP that has the diameter W1 and through which the upper surface of the p-contact layer 19 is exposed. The p electrode 23 that makes ohmic contact with the p-contact layer 19 exposed through the contact opening OP and fills the contact opening OP is provided.

The p electrode 23 is formed of a light-transmissive electric conductor, and is formed of, for example, indium tin oxide (ITO). The diameter of the contact opening OP, in other words, the diameter W1 of the current injection region 23R is 500 μm, and the layer thickness of the p electrode 23 is 135 nm.

A silver alloy (Ag alloy) layer as the light-reflecting layer 24 is provided on the p electrode 23. The light-reflecting layer 24 is provided so as to cover at least the entirety of the contact opening OP in a top view. The light-reflecting layer 24 has a flat surface parallel to the air-hole layer 14P. The light-reflecting layer 24 has a layer thickness of, for example, 150 nm.

The pad electrode 32 is provided on the light-reflecting layer 24. The pad electrode 32 is bonded to the heat-dissipating substrate 225 (submount) made of diamond through a wiring electrode 224P on a heat-dissipating substrate 225 by a bonding metal 224.

The thermal conductivity adjustment layer 221 is provided on a bonded surface (lower surface) of the heat-dissipating substrate 225. The thermal conductivity adjustment layer 221 includes a first layer 221A having an opening that is coaxial with the central axis CZ of the p electrode 23 and has the diameter W2 (W2<W1), and a second layer 221B provided on the lower surface side of the first layer 221A and having an opening that is coaxial with the central axis CZ and has the diameter W4 (W2<W4<W1). In other words, the first layer 221A and the second layer 221B are formed as layers having circular openings in a section parallel to the air-hole layer 14P (in other words, the semiconductor structure layer 11). Specifically, the diameter W2 of the first layer 221A, which is the opening diameter of the thermal conductivity adjustment layer 221, is smaller than the diameter W1 (contact opening diameter) of the current injection region 23R (W2<W1).

The first layer 221A and the second layer 221B (hereinafter also collectively referred to as the thermal conductivity adjustment layer 221) are made of SiO₂, the first layer 221A has a layer thickness of 20 nm, and the second layer 221B has a layer thickness of 120 nm. The opening diameter W2 of the first layer 221A is, for example, 240 μm, and the opening diameter W4 of the second layer 221B is, for example, 400 μm.

A layer including at least one material selected from insulators and semiconductors having a thermal conductivity lower than at least that of the heat-dissipating substrate 225 or the bonding metal 224 may be used as the thermal conductivity adjustment layer 221. For example, oxides (such as SiO₂, Al₂O₃, Ta₂O₅, ZrO₂, and HfO₂), nitrides (such as SiNx), and oxynitrides (such as SiON and AlON) may be used. Note that an oxide insulator such as SiO₂ is preferable as the thermal conductivity adjustment layer 221 because of low thermal conductivity and high electric resistance.

The thermal conductivity adjustment layer 221 is adhered to the heat-dissipating substrate 225 through an adhesion layer 222A provided between the heat-dissipating substrate 225 and the first layer 221A of the thermal conductivity adjustment layer 221, and is adhered to the bonding metal 224 through an adhesion layer 222B provided between the bonding metal 224 and the second layer 221B.

The adhesion layer 222A and the adhesion layer 222B (hereinafter also collectively referred to as an adhesion layer 222) may be, for example, Ti/Pu/Au layers, but are not limited thereto.

The bonding metal 224 buries the thermal conductivity adjustment layer 221 by covering the entirety of the thermal conductivity adjustment layer 221 and is bonded to the heat-dissipating substrate 225.

Note that the heat-dissipating substrate 225 is not limited to diamond but may be made of AlN, SiC, graphite, CuW, Cu-diamond, Ag-diamond, or the like.

### (2) Element Evaluation

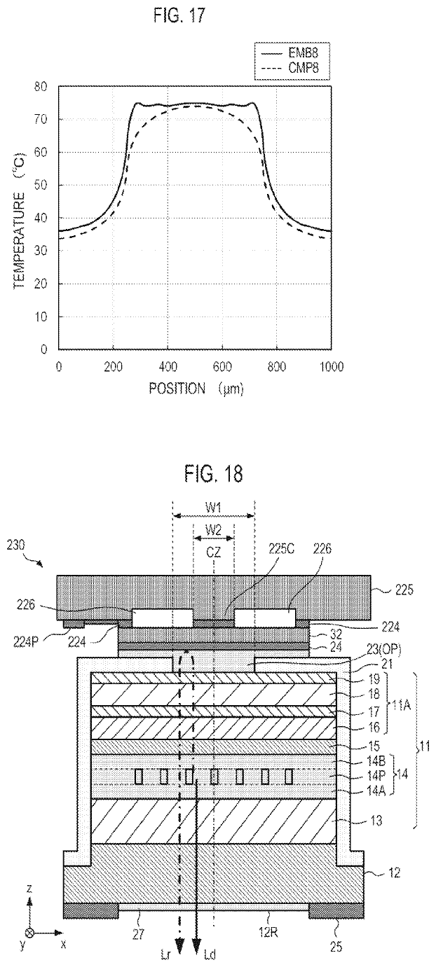

FIG. 17 is a graph illustrating calculation results of temperature distribution in the air-hole layer for a PCSEL element 220 (EMB8) according to the present embodiment and a PCSEL element (CMP8) according to the comparative example in comparison. Note that the comparative example (CMP8) is different from the PCSEL element 220 (EMB8) according to the present embodiment only in that the comparative example (CMP8) does not include the thermal conductivity adjustment layer 221 and the adhesion layer 222.

As illustrated in FIG. 17, it can be understood that temperature distribution in the air-hole layer 14P of the PCSEL element 220 (EMB8) is flat as compared to the comparative example (CMP8). Specifically, it can be understood that the diameter of a region in which effective oscillation is possible is 467 μm (based on the above-described criterion for ΔT≤4° C.), the oscillation area increases as compared to the diameter 318 μm of a region in which oscillation is possible in the comparative example (CMP8A), thereby improving efficiency.

Such an effect occurs for the first time when the diameter W2 of an opening 221R (thermal conductivity adjustment opening) of the thermal conductivity adjustment layer 221 is made smaller than the diameter W1 of the current injection region 23R (contact region) (W2<W1). Accordingly, with the PCSEL element according to the present embodiment, it is possible to solve degradation of oscillation characteristics due to temperature distribution in the air-hole layer (photonic crystal layer), which is a problem unique to the PCSEL element.

Thus, it is possible to prevent increase in threshold current during continuous wave (CW) drive by providing a thermal conductivity adjustment layer, thereby improving the light emission efficiency. Moreover, it is possible to provide a surface-emitting laser with excellent oscillation stability such as single-mode stability.

In the PCSEL element 220 according to the present embodiment, the thermal conductivity adjustment layer 221 is provided on the heat-dissipating substrate 225 side, apart from the p electrode 23 (contact electrode). Accordingly, compared to a case where the thermal conductivity adjustment layer is provided near the p electrode 23, injection current from the wiring electrode 224P on the heat-dissipating substrate 225 connected to the bonding metal 224 is not obstructed by the thermal conductivity adjustment layer 221, which enables uniform current injection.

Since in-plane nonuniformity of current injection would lead to degradation of device characteristics and reliability, it is possible to improve the characteristics by the PCSEL element according to the present embodiment.

Note that, in the present embodiment, description is made of the case where the thermal conductivity adjustment layer 221 is constituted by two layers with different opening diameters, but the thermal conductivity adjustment layer 221 may be constituted by a single layer having an opening with the diameter W2. Alternatively, the thermal conductivity adjustment layer 221 may be formed as a tapered layer having a layer thickness that decreases toward the opening center.

### (3) Modification 1

FIG. 18 is a cross-sectional view schematically illustrating the structure of a PCSEL element 230 according to Modification 1 of the eighth embodiment. Note that a section including the central axis CZ of the p electrode 23 is illustrated.

In the PCSEL element 230 according to Modification 1, a thermal conductivity adjustment layer 226 is formed as a cavity (space layer) provided in the heat-dissipating substrate 225. The heat-dissipating substrate 225 is made of, for example, aluminum nitride (AlN).

More specifically, the thermal conductivity adjustment layer 226 includes a concave portion recessed from the lower surface (in other words, bonded surface to the bonding metal 224) of the heat-dissipating substrate 225. The thermal conductivity adjustment layer 226 has a cylindrical inner wall surface. Accordingly, the heat-dissipating substrate 225 includes a cylindrical convex portion 225C that is coaxial with the central axis CZ of the p electrode 23 and has the diameter W2 (W2<W1).

When the lower surface of the heat-dissipating substrate 225 where the concave portion is formed is bonded to the pad electrode 32, the thermal conductivity adjustment layer 226 is formed as a cavity (space layer) in the heat-dissipating substrate 225 between the heat-dissipating substrate 225 and the pad electrode 32.

The thermal conductivity adjustment layer 226 as a cavity can be formed, for example, as described below. First, an AlN substrate is dry-etched by using an ICP-RIE device to form the cylindrical convex portion 225C and a concave portion recessed from the surface of a peripheral portion of the heat-dissipating substrate 225 about the convex portion 225C. The concave portion is formed in a circular annular shape in a top view, for example.

Subsequently, in order to suppress the spread of molten metal during bonding with the pad electrode 32, a bonding metal film 224 made of Ti/Pt/Au is patterned and deposited only in a bonding region of the heat-dissipating substrate 225.

Subsequently, the pad electrode 32 is bonded to the bonding region of the heat-dissipating substrate 225. Note that, since solder such as AuSn spreads when melted and is unlikely to form cavities, it is preferable to use bonding such as Au-Au bonding by which molten spread is unlikely to occur.

### (4) Modification 2

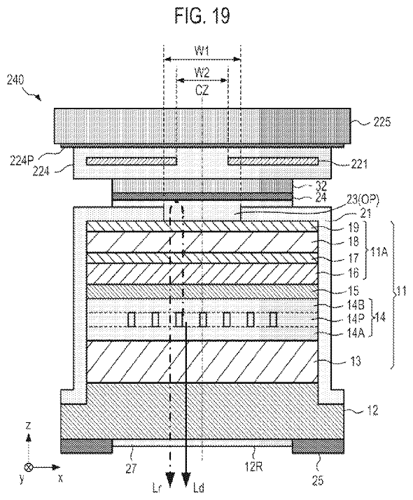

FIG. 19 is a cross-sectional view schematically illustrating the structure of a PCSEL element 240 according to Modification 2 of the eighth embodiment.

In the PCSEL element 240 according to Modification 2, the thermal conductivity adjustment layer 221 is entirely buried inside the bonding metal 224. The thermal conductivity adjustment layer 221 has an opening that is coaxial with the central axis CZ of the p electrode 23 and has the diameter W2 that is smaller than the opening diameter W1 of the contact opening OP (W2<W1), which is the same configuration as in the PCSEL elements according to the above-described embodiments.

### (5) Modification 3

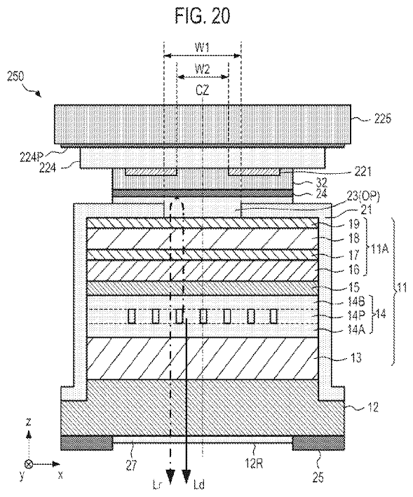

FIG. 20 is a cross-sectional view schematically illustrating the structure of a PCSEL element 250 according to Modification 3 of the eighth embodiment.

In the PCSEL element 250 according to Modification 3, the thermal conductivity adjustment layer 221 is provided on the upper surface of the pad electrode 32, in contact with the bonding metal 224. The thermal conductivity adjustment layer 221 has an opening that is coaxial with the central axis CZ of the p electrode 23 and has the diameter W2 (W2<W1), which is the same configuration as in the PCSEL element 240 according to Modification 2.

### (6) Modification 4

FIG. 21 is a cross-sectional view schematically illustrating the structure of a PCSEL element 260 according to Modification 4 of the eighth embodiment.

In the PCSEL element 260 according to Modification 4, the thermal conductivity adjustment layer 221 is buried in the bonding metal 224, in contact with the pad electrode 32. The thermal conductivity adjustment layer 221 has an opening that is coaxial with the central axis CZ of the p electrode 23 and has the diameter W2 (W2<W1), which is the same configuration as in the PCSEL elements according to the above-described embodiments.

Thus, in the PCSEL element according to the present embodiment, it is possible to prevent increase in threshold current during continuous wave (CW) drive by providing the thermal conductivity adjustment layer, thereby improving the light emission efficiency. Moreover, it is possible to provide a surface-emitting laser with excellent oscillation stability such as single-mode stability.

### Ninth Embodiment

### (1) Element Structure

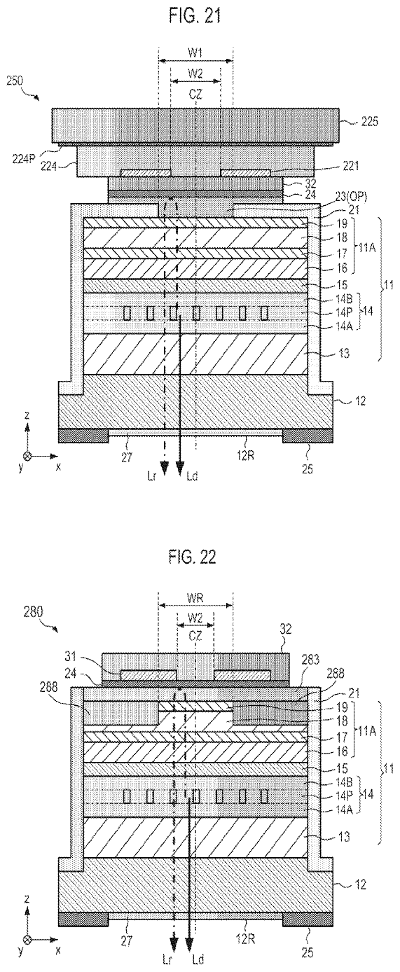

FIG. 22 is a cross-sectional view schematically illustrating the structure of a PCSEL element 280 according to a ninth embodiment. The PCSEL element 280 according to the present embodiment includes the same thermal conductivity adjustment layer 31 as in the PCSEL element 10 according to the first embodiment.

The PCSEL element 280 further includes a refractive index adjustment layer 288 embedded and formed in the second semiconductor layer. More specifically, the refractive index adjustment layer 288 is embedded in the p-clad layer 18 and the p-contact layer 19.

In the PCSEL element 280, the refractive index adjustment layer 288 is constituted by, for example, an AlₓIn_{y}Ga_{1-x-y}N layer (0≤x≤1, 0≤y≤1, 0≤x+y≤1) (semiconductor heterostructure), and is formed as a layer extending from a position shallower than the lower surface of the p-clad layer 18 to the upper surface of the p-contact layer 19.

A p electrode 283 (p contact electrode) is formed on the p-contact layer 19 and the refractive index adjustment layer 288. The light-reflecting layer 24 is formed on the p electrode 283 made of a light-transmissive electric conductor, and the pad electrode 32 in which the thermal conductivity adjustment layer 31 is buried is provided on the light-reflecting layer 24, which is the same configuration as in the PCSEL element 10 according to the first embodiment.

More specifically, the refractive index adjustment layer 288 has a cylindrical opening that is coaxial with the central axis CZ of the opening of the thermal conductivity adjustment layer 31, and the cylindrical opening has a diameter WR of 500 μm. Accordingly, the refractive index adjustment layer 288 is formed such that the cylindrical opening of the refractive index adjustment layer 288 is filled with part of the p-clad layer 18 and the p-contact layer 19. The refractive index adjustment layer 288 has a refractive index higher than the effective refractive indexes of the p-clad layer 18 and the p-contact layer 19 included in the cylindrical opening.

Note that the refractive index adjustment layer 288 also functions as a current confinement layer. In other words, the cylindrical region functions as the current injection region. Thus, the diameter (opening diameter) WR of the cylindrical opening is larger than the opening diameter (diameter) W2 of the thermal conductivity adjustment layer 31 (W2<WR).

In the refractive index adjustment layer 288 (AlInGaN), for example, the p-contact layer 19 and the p-clad layer 18 were etched by dry etching, and then the etched portion was subjected to embedment growth by a MOVPE method. The refractive index adjustment layer 288 is not limited to the MOVPE method but may be formed by an MBE method or sputtering. In the PCSEL element 280, the refractive index adjustment layer 288 is formed at a depth of approximately 320 nm.

Note that ZrO₂, TiO₂, Ta₂O₅, Nb₂O₅, SiNx, or the like may be used as the refractive index adjustment layer 288.

### (2) Element Evaluation

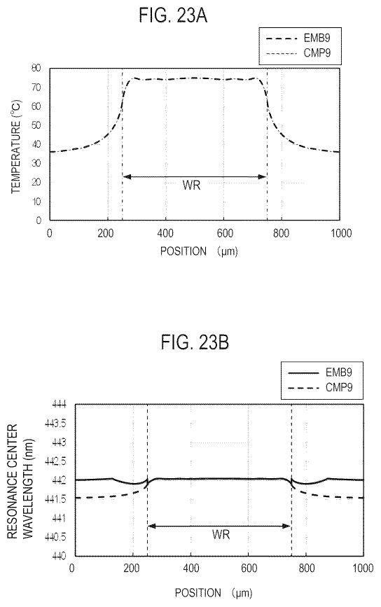

FIG. 23A is a graph illustrating calculation results of temperature distribution in the air-hole layer for the PCSEL element 280 (EMB9) according to the present embodiment and a PCSEL element (CMP9) according to the comparative example in comparison. Note that the PCSEL element according to the comparative example is different from the PCSEL element 280 only in that the PCSEL element according to the comparative example does not include the refractive index adjustment layer 288. In the embodiment, application voltage of 6V and injection current of 7A to the element are assumed.

As illustrated in FIG. 23A, it can be understood that there is no large difference in temperature distribution between the PCSEL element 280 (EMB9) according to the present embodiment and the PCSEL element (CMP9) according to the comparative example (they overlap in the drawing), and temperature distribution in the current injection region (diameter WR) is flat.

FIG. 23B is a graph illustrating calculation results of the resonance center wavelength (nm) for the PCSEL element 280 (EMB9) according to the present embodiment and the PCSEL element (CMP9) according to the comparative example in comparison. In this calculation, the Bragg reflection wavelength is calculated based on the effective refractive index in consideration of temperature and the lattice constant of the photonic crystal.

It can be understood that the resonance wavelength is shifted between the inside and outside of the current injection region in the comparative example in which no refractive index adjustment layer is provided, whereas the shift in the resonance wavelength is alleviated in the PCSEL element 280 according to the present embodiment. Accordingly, light diffraction is obtained even from outside the current injection region, which reduces in-plane light leakage and allows for loss reduction. In other words, the efficiency of the PCSEL element can be improved.

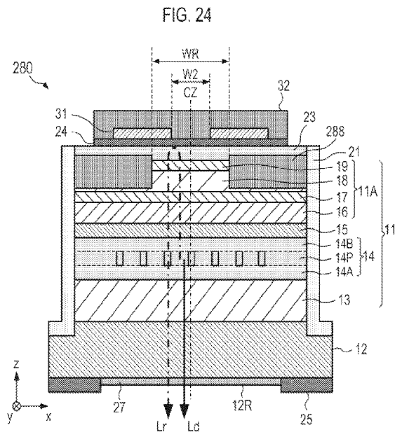

Note that the refractive index adjustment layer 288 is embedded and formed in the second semiconductor layer, and is preferably formed as a layer provided between the lower surface of the p-clad layer 18 and the upper surface of the p electrode 23 as illustrated in FIG. 24. In this case, the refractive index adjustment layer 288 may have a refractive index higher than the effective refractive index of the entirety of the p-clad layer 18 and the p-contact layer 19, which are included in the cylindrical region of the refractive index adjustment layer 288, and the p electrode 23.

The embodiments of the present invention are described above in detail. Note that, in the above-described embodiments, the shapes of the contact opening (current injection region) and the thermal conductivity adjustment opening of the p electrode (contact electrode) and the thermal conductivity adjustment layer, respectively, are preferably circular in a top view, but not limited thereto. The openings may have, for example, elliptical shapes, polygonal shapes, substantially circular shapes (including gear shapes) having periodic concavities and convexities on the outer periphery, and multiple-ring shapes. Thus, in the present specification, the term “circular shape” includes elliptical shapes, substantially circular shapes having periodic concavities and convexities on the outer periphery, and multiple-ring shapes.

In a case where the shapes of the contact opening (current injection region) and the thermal conductivity adjustment opening are non-circular, the shapes are preferably rotationally symmetric with respect to the central axis. In these cases, each opening diameter is defined as the diameter (or major radius) of a circle (including an ellipse) that the opening shape circumscribes.

In order to achieve two-dimensional uniform adjustment of temperature distribution, the contact opening (current injection region) and the thermal conductivity adjustment opening more preferably have circular shapes or regular n-gon shapes (where n is an integer of four or more) in a top view, and further more preferably have circular shapes.

The thermal conductivity adjustment opening preferably has a similar shape having a central axis that is coaxial with the contact opening. Specifically, it is sufficient that the thermal conductivity adjustment opening is disposed with sizes such that the thermal conductivity adjustment opening region is contained within the current injection region in a top view, and the shapes of the p electrode (contact electrode) and the thermal conductivity adjustment layer are determined such that temperature distribution is flattened in a manner that temperature in the outer peripheral portion of the current injection region is uniform with temperature in its central portion.

The above-described various embodiments may be modified or applied in combination as appropriate within the scope of the present invention.

As described above, according to the present invention, it is possible to provide a photonic-crystal surface-emitting laser in which temperature distribution in a photonic crystal can be easily flattened during continuous wave (CW) drive, thereby improving light emission efficiency and achieving excellent oscillation stability.

### REFERENCE SIGNS LIST

10, 60, 70, 80, 90, 210, 220, 230, 240, 250, 260, 280: PCSEL element
11: semiconductor structure layer
11A: second semiconductor layer
14: first guide layer
14P: air-hole layer
14K: air hole
15: active layer
19: contact layer
23, 213: p electrode (contact electrode)
23R, 213R: current injection region
24, 214: light-reflecting layer
31, 33, 35, 211, 221: thermal conductivity adjustment layer
32, 215: pad electrode
226: thermal conductivity adjustment layer (cavity)
31W, 35W, 37W, 211R, 221R: thermal conductivity adjustment opening
215A: metal electrode
224: bonding metal
225: heat-dissipating substrate
288: refractive index adjustment layer
OP: contact opening

1. A surface-emitting laser element comprising a photonic crystal, the surface-emitting laser element comprising:
a substrate that is light-transmissive;
a first semiconductor layer which is formed on the substrate and in which an air-hole layer that serves as a photonic crystal layer is formed;
an active layer formed on the first semiconductor layer;
a second semiconductor layer formed on the active layer;
a current confinement layer formed on the second semiconductor layer and having a contact opening in a circular shape or a rotationally symmetric shape;
a contact electrode formed by filling the contact opening of the current confinement layer; and
a pad electrode which is formed on the contact electrode and inside which a thermal conductivity adjustment layer having a thermal conductivity lower than an effective thermal conductivity of the second semiconductor layer is buried, wherein
the thermal conductivity adjustment layer has a thermal conductivity adjustment opening having a central axis that is coaxial with the contact opening, and the thermal conductivity adjustment opening has an opening diameter (W2) smaller than an opening diameter (W1) of the contact opening.

2. The surface-emitting laser element according to claim 1, wherein the thermal conductivity adjustment opening has a similar shape having a central axis that is coaxial with the contact opening.

3. The surface-emitting laser element according to claim 2, wherein
the thermal conductivity adjustment opening has a circular shape, and
the thermal conductivity adjustment layer includes an outer peripheral portion and an inner peripheral portion having a circular annular shape and a layer thickness smaller than the outer peripheral portion.

4. The surface-emitting laser element according to claim 1, wherein the thermal conductivity adjustment layer has a layer thickness that decreases in a tapered shape toward the center of the thermal conductivity adjustment opening, and includes an inner peripheral portion having an annular shape similar to the contact opening.

5. The surface-emitting laser element according to claim 1, wherein a light-reflecting layer is provided between the pad electrode and the contact electrode.

6. The surface-emitting laser element according to claim 1, wherein the second semiconductor layer is made of a gallium nitride (GaN)-based semiconductor, and the thermal conductivity adjustment layer is formed to include a material having a thermal conductivity lower than the thermal conductivity of GaN.

7. The surface-emitting laser element according to claim 1, wherein the thermal conductivity adjustment layer is formed in a dot pattern.

8. A surface-emitting laser element comprising a photonic crystal, the surface-emitting laser element comprising:
a substrate that is light-transmissive;
a first semiconductor layer which is formed on the substrate and in which an air-hole layer that serves as a photonic crystal layer is formed;
an active layer formed on the first semiconductor layer;
a second semiconductor layer formed on the active layer;
a light-transmissive contact electrode that is partially formed on the second semiconductor layer and is in ohmic contact with the second semiconductor layer;
a thermal conductivity adjustment layer that is formed on the second semiconductor layer, overlaps an outer peripheral portion of the contact electrode, has a thermal conductivity adjustment opening formed so as to partially cover an upper surface of the outer peripheral portion and expose the contact electrode, and is constituted by a layer including at least one material selected from insulators and semiconductors having a thermal conductivity lower than an effective thermal conductivity of the second semiconductor layer; and
a light-reflecting metal electrode formed so as to fill the thermal conductivity adjustment opening of the thermal conductivity adjustment layer and cover at least an entirety of the contact electrode in a top view.

9. The surface-emitting laser element according to claim 8, wherein the contact electrode and the opening of the thermal conductivity adjustment layer have either a circular shape and a rotationally symmetric shape that are coaxial with each other in a top view.

10. The surface-emitting laser element according to claim 8, wherein the contact electrode is a light-transmissive electric conductor, and the metal electrode is constituted by a light-reflecting layer formed on the contact electrode and a pad electrode formed on the light-reflecting layer.

11. A surface-emitting laser element comprising a photonic crystal, the surface-emitting laser element comprising:
a substrate that is light-transmissive;
a first semiconductor layer which is formed on the substrate and in which an air-hole layer that serves as a photonic crystal layer is formed;
an active layer formed on the first semiconductor layer;
a second semiconductor layer formed on the active layer;
a current confinement layer formed on the second semiconductor layer and having a contact opening;
a contact electrode formed by filling the contact opening of the current confinement layer;
a metal electrode formed on the contact electrode;
a bonding metal formed on the metal electrode;
a heat-dissipating substrate bonded to the bonding metal by the bonding metal; and
a thermal conductivity adjustment layer provided inside one of the metal electrode, the bonding metal, and the heat-dissipating substrate, wherein
the thermal conductivity adjustment layer includes at least one material selected from insulators and semiconductors having a thermal conductivity lower than at least one of the bonding metal and the heat-dissipating substrate, and
the thermal conductivity adjustment layer has a thermal conductivity adjustment opening, and the thermal conductivity adjustment opening has a size and disposition such that the thermal conductivity adjustment opening is contained within the contact opening in a top view.

12. The surface-emitting laser element according to claim 11, wherein the contact opening and the opening of the thermal conductivity adjustment layer have either a circular shape and a rotationally symmetric shape that are coaxial with each other in a top view.

13. The surface-emitting laser element according to claim 12, wherein the thermal conductivity adjustment layer is provided on a lower surface of the heat-dissipating substrate.

14. The surface-emitting laser element according to claim 12, wherein the thermal conductivity adjustment layer is a cavity formed in the heat-dissipating substrate between the heat-dissipating substrate and the bonding metal.

15. The surface-emitting laser element according to claim 12, wherein the thermal conductivity adjustment layer is provided inside the bonding metal.

16. The surface-emitting laser element according to claim 12, wherein the thermal conductivity adjustment layer is provided in the metal electrode at an interface between the metal electrode and the bonding metal.

17. The surface-emitting laser element according to claim 11, wherein
a refractive index adjustment layer is embedded in the second semiconductor layer,
the refractive index adjustment layer is embedded and formed such that an opening region having a cylindrical shape and coaxial with a central axis of the contact electrode is filled with part of the second semiconductor layer, and
the thermal conductivity adjustment opening has an opening diameter smaller than an opening diameter of the cylindrical shape of the refractive index adjustment layer.

18. The surface-emitting laser element according to claim 17, wherein
the second semiconductor layer includes a p-side guide layer formed on the active layer, an electron blocking layer formed on the p-side guide layer, a p-clad layer formed on the electron blocking layer, and a p-contact layer formed on the p-clad layer, and
the refractive index adjustment layer is formed as a layer extending from a position shallower than a lower surface of the p-clad layer to an upper surface of the p-contact layer.
